(19) United States
(12) Patent Application Publication
(10) Pub. No.: US 2026/0065947 A1
(43) Pub. Date: Mar. 5, 2026

(54) SEMICONDUCTOR MEMORY DEVICE HAVING INDUCTOR

(71) Applicant: SK hynix Inc., Icheon-si (KR)

(72) Inventors: Beom Kyu SEO, Icheon-si (KR); Sung Hwa OK, Icheon-si (KR); Jun Seo JANG, Icheon-si (KR); Eun Ji CHOI, Icheon-si (KR); Jae Hyeong HONG, Icheon-si (KR)

(21) Appl. No.: 19/042,597

(22) Filed: Jan. 31, 2025

(30) Foreign Application Priority Data
Aug. 28, 2024 (KR) 10-2024-0116014

(51) Int. Cl. G11C 5/06; G11C 16/10; G11C 16/26; H10B 43/10; H10B 43/40

(52) U.S. Cl. CPC G11C 5/06; G11C 16/10; G11C 16/26; H10B 43/10; H10B 43/40

(57) ABSTRACT

A semiconductor memory device includes a substrate; a peripheral structure including a plurality of lower wiring layers that are vertically stacked on the substrate; a memory structure disposed on the peripheral structure, and including a memory cell array in a first region; an input/output pad disposed over the memory structure in a second region; and an inductor disposed in at least one of the plurality of lower wiring layers and to vertically overlap the input/output pad.

### CROSS-REFERENCE TO RELATED APPLICATION

The present application claims priority under 35 U.S.C. § 119(a) to Korean Patent Application No. 10-2024-0116014 filed in the Korean Intellectual Property Office on Aug. 28, 2024, which is incorporated herein by reference in its entirety.

### BACKGROUND

### 1. Technical Field

The present disclosure relates to semiconductor technology, and more particularly, to a semiconductor memory device having inductor.

### 2. Related Art

As operating speeds of semiconductor memory devices increase, data rates are also increasing. If data rates increase while channel characteristics are maintained, then signal integrity (SI) characteristics deteriorate, and thus, measures for improving SI characteristics are being studied.

### SUMMARY

Various embodiments of the present disclosure are directed to semiconductor memory devices having inductors.

In an embodiment, a semiconductor memory device may include: a substrate; a peripheral structure including a plurality of lower wiring layers that are vertically stacked on the substrate; a memory structure disposed on the peripheral structure, and including a memory cell array in a first region; an input/output pad disposed over the memory structure in a second region; and an inductor disposed in at least one of the plurality of lower wiring layers, and to vertically overlap the input/output pad.

In an embodiment, a semiconductor memory device may include: a substrate; a peripheral structure including a first lower wiring layer over the substrate and a second lower wiring layer over the first lower wiring layer; a memory structure disposed on the peripheral structure, and including a three-dimensional memory cell array in a first region; an input/output pad disposed over the memory structure in a second region; a first inductor disposed in the first lower wiring layer to vertically overlap the input/output pad; and a second inductor disposed in the second lower wiring layer to vertically overlap the input/output pad.

According to the embodiments of the present disclosure, by disposing an inductor to overlap an input/output pad, it is possible to suppress an increase in layout area due to the presence of the inductor.

According to the embodiments of the present disclosure, by disposing an inductor to overlap an input/output pad and increasing gain at high frequency and enhancing cut-off frequency by using the inductor, it is possible to improve signal integrity (SI) characteristics without an increase in layout area.

### BRIEF DESCRIPTION OF THE DRAWINGS

FIG. 1 is a cross-sectional view of a semiconductor memory device according to embodiments of the present disclosure.

FIG. 2 is a plan view illustrating an input/output pad and inductors of FIG. 1.

FIG. 3 is a block diagram illustrating a system including a semiconductor memory device according to embodiments of the present disclosure.

FIGS. 4 and 5 are circuit diagrams illustrating an input buffer of semiconductor memory devices according to embodiments of the present disclosure.

FIGS. 6 and 7 are circuit diagrams illustrating a termination circuit of semiconductor memory devices according to embodiments of the present disclosure.

FIG. 8 is a circuit diagram illustrating an amplifier circuit of a semiconductor memory device according to an embodiment of the present disclosure.

FIG. 9 is a cross-sectional view of a semiconductor memory device according to an embodiment of the present disclosure.

FIGS. 10 and 11 are circuit diagrams illustrating an input buffer of semiconductor memory devices according to embodiments of the present disclosure.

FIGS. 12 and 13 are circuit diagrams illustrating a termination circuit of semiconductor memory devices according to embodiments of the present disclosure.

FIG. 14 is a circuit diagram illustrating an amplifier circuit of a semiconductor memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

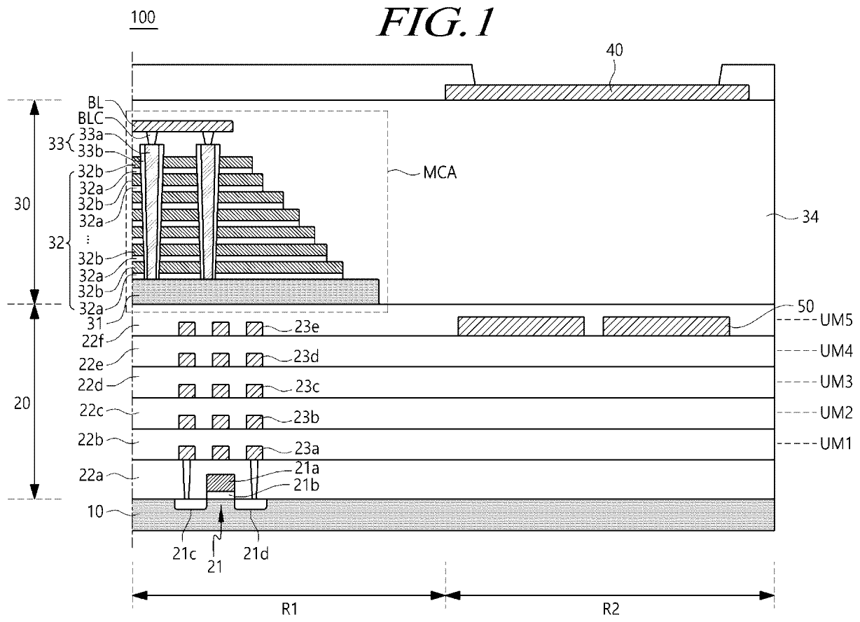

FIG. 1 is a cross-sectional view of a semiconductor memory device according to embodiments of the present disclosure.

Referring to FIG. 1, a semiconductor memory device 100 includes a substrate 10, a peripheral structure 20, a memory structure 30, an input/output pad 40, and inductors 50.

The inductor 50 is disposed in a fifth lower wiring layer UM5 of the peripheral structure 20 and vertically overlaps the input/output pad 40.

The semiconductor memory device 100 includes a first region R1 and a second region R2. In an embodiment, the second region R2 may be an edge region of the semiconductor memory device 100. In another embodiment, the second region R2 may be a central region of the semiconductor memory device 100.

The peripheral structure 20 is disposed on the substrate 10. The peripheral structure 20 includes a circuit element 21, lower wiring layers UM1, UM2, UM3, UM4 and UM5 and lower dielectric layers 22a, 22b, 22c, 22d, 22e and 22f.

The circuit element 21 is disposed in the first region R1 of the substrate 10. The circuit element 21 includes a transistor. The transistor includes a first gate electrode 21a which is disposed on the substrate 10, a first gate insulating layer 21b between the substrate 10 and the first gate electrode 21a, and a source region 21c and a drain region 21d, which are defined in the substrate 10 on both sides of the first gate electrode 21a. The circuit element 21 may a component of a peripheral circuit for controlling the operation of a memory cell array. The peripheral circuit may include, for example, a row decoder, a page buffer circuit, a control logic, a voltage generator and a receiving interface circuit, but embodiments is not limited thereto.

The lower wiring layers UM1, UM2, UM3, UM4 and UM5 include a first lower wiring layer UM1 on the substrate 10, a second lower wiring layer UM2 on the first lower wiring layer UM1, a third lower wiring layer UM3 on the second lower wiring layer UM2, a fourth lower wiring layer UM4 on the third lower wiring layer UM3, and the fifth lower wiring layer UM5 on the fourth lower wiring layer UM4. Although FIG. 1 illustrates five lower wiring layers, embodiments of the present disclosure are not limited thereto. In other embodiments, the semiconductor memory device 100 includes at least two lower wiring layers. In the first region R1, wirings 23a, 23b, 23c, 23d and 23e are disposed in the first, second, third, fourth and fifth lower wiring layers UM1, UM2, UM3, UM4 and UM5, respectively.

The lower dielectric layers 22a, 22b, 22c, 22d, 22e and 22f include a first lower dielectric layer 22a, a second lower dielectric layer 22b, a third lower dielectric layer 22c, a fourth lower dielectric layer 22d, a fifth lower dielectric layer 22e and a sixth lower dielectric layer 22f. The first, second, third, fourth, fifth and sixth lower dielectric layers 22a, 22b, 22c, 22d, 22e and 22f may include silicon oxide, silicon nitride or silicon oxynitride.

The first lower dielectric layer 22a is disposed on the substrate 10 and covers the circuit element 21. The first lower wiring layer UM1 is disposed on the first lower dielectric layer 22a. The second lower dielectric layer 22b is disposed on the first lower dielectric layer 22a and covers the first lower wiring layer UM1.

The second lower wiring layer UM2 is disposed on the second lower dielectric layer 22b. The third lower dielectric layer 22c is disposed on the second lower dielectric layer 22b and covers the second lower wiring layer UM2.

The third lower wiring layer UM3 is disposed on the third lower dielectric layer 22c. The fourth lower dielectric layer 22d is disposed on the third lower dielectric layer 22c and covers the third lower wiring layer UM3.

The fourth lower wiring layer UM4 is disposed on the fourth lower dielectric layer 22d. The fifth lower dielectric layer 22e is disposed on the fourth lower dielectric layer 22d and covers the fourth lower wiring layer UM4.

The fifth lower wiring layer UM5 is disposed on the fifth lower dielectric layer 22e. The sixth lower dielectric layer 22f is disposed on the fifth lower dielectric layer 22e and covers the fifth lower wiring layer UM5.

The fifth lower wiring layer UM5 may be an uppermost lower wiring layer, which is a layer closest to the memory structure 30 from among the lower wiring layers UM1, UM2, UM3, UM4 and UM5 of the peripheral structure 20.

The memory structure 30 is disposed on the peripheral structure 20. The memory structure 30 includes a memory cell array MCA and an upper dielectric layer 34. The memory cell array MCA is disposed in the first region R1.

The memory cell array MCA includes a source plate 31, a gate stack 32 and a plurality of cell plugs 33.

The source plate 31 is disposed on the peripheral structure 20. The source plate 31 includes a doped semiconductor.

The gate stack 32 includes a plurality of interlayer insulating layers 32a and a plurality of gate electrode layers 32b, which are alternately stacked on the source plate 31. The interlayer insulating layers 32a include silicon oxide. The gate electrode layers 32b include a conductive material. The conductive material includes, for example, tungsten (W). A gate electrode layer 32b may constitute a word line.

The cell plug 33 may extend to the source plate 31 by vertically passing through the gate stack 32. The cell plug 33 includes a channel layer 33a and a cell gate insulating layer 33b. The cell gate insulating layer 33b may have the shape of a straw or a cylindrical shell that surrounds the outer wall of the channel layer 33a. The cell gate insulating layer 33b may include a tunnel insulating layer, a charge storage layer and a blocking layer, which are sequentially stacked from the outer sidewall of the channel layer 33a. In some embodiments, the cell gate insulating layer 33b may have an ONO (oxide-nitride-oxide) stack structure in which an oxide layer, a nitride layer and an oxide layer are sequentially stacked.

Memory cells may be configured where word lines surround the cell plugs 33. Memory cells that are vertically disposed along one cell plug 33 are included in a cell string. A plurality of cell strings may be configured in correspondence to the plurality of cell plugs 33, and memory cells may be arranged in a three-dimensional manner. The memory structure 30 may include a three-dimensional memory cell array.

A bit line BL is disposed on the gate stack 32 and the cell plugs 33. A bit line contact BLC is disposed under the bit line BL to connect the bit line BL and the channel layer 33a.

The upper dielectric layer 34 is disposed in both the first region R1 and the second region R2 of the peripheral structure 20. The upper dielectric layer 34 covers the peripheral structure 20, the source plate 31, the gate stack 32, the cell plugs 33, and the bit line BL.

The input/output pad 40 is disposed in the second region R2 of the memory structure 30. The inductor 50 is disposed in the fifth lower wiring layer UM5 of the peripheral structure 20 and vertically overlaps the input/output pad 40.

The size of elements included in semiconductor memory devices is being reduced for integration. If the size of inductors is reduced, a quality factor (Q-factor) deteriorates and a parasitic capacitance component increases. Therefore, size reduction of inductors is more complex compared to size reduction in other elements. According to the embodiments of the present disclosure, because the inductor 50 is disposed to vertically overlap with the input/output pad 40, an increase in the size of the semiconductor memory device 100 due to the presence of the inductor 50 may be avoided.

The inductor 50 is disposed in the fifth lower wiring layer UM5, which is an uppermost layer among the lower wiring layers UM1, UM2, UM3, UM4 and UM5 included in the peripheral structure 20. A conductive pattern is not disposed between the inductor 50 and the substrate 10. The first to fifth lower dielectric layers 22a to 22e are disposed between the substrate 10 and the inductor 50.

The parasitic capacitance between the substrate 10 and the inductor 50 is inversely proportional to the thickness of the dielectric between the substrate 10 and the inductor 50. Because the inductor 50 is disposed in the fifth lower wiring layer UM5, which is an uppermost layer among the lower wiring layers UM1, UM2, UM3, UM4 and UM5 included in the peripheral structure 20, the parasitic capacitance between the inductor 50 and the substrate 10 has a smaller value when compared to a case where the inductor 50 is disposed in a lower wiring layer other than the fifth lower wiring layer UM5.

Although the inductor 50 in FIG. 1 is disposed on the fifth lower wiring layer UM5, which is an uppermost layer among the lower wiring layers UM1, UM2, UM3, UM4 and UM5, the present disclosure is not limited thereto. For example, if the parasitic capacitance between the inductor 50 and the substrate 10 is smaller than a preset threshold value, then the inductor 50 may be disposed in a lower wiring layer other than the fifth lower wiring layer UM5. In addition, inductors may be disposed in at least two lower wiring layers.

The sixth lower dielectric layer 22f and the upper dielectric layer 34 are disposed between the inductor 50 and the input/output pad 40. The thickness of the upper dielectric layer 34 between the inductor 50 and the input/output pad 40 is greater than the thickness of the gate stack 32. The parasitic capacitance between the inductor 50 and the input/output pad 40 is inversely proportional to the thickness of the dielectric between the inductor 50 and the input/output pad 40. A conductive pattern is not disposed between the inductor 50 and the input/output pad 40.

Because a conductive pattern is not disposed between the inductor 50 and the input/output pad 40, and the upper dielectric layer 34 which has a thickness greater than the thickness of the gate stack 32 is disposed between the inductor 50 and the input/output pad 40, the parasitic capacitance between the inductor 50 and the input/output pad 40 has a small value. When the number of gate electrode layers 32b that are stacked is increased for high capacity applications, the height of the gate stack 32 increases and the thickness of the upper dielectric layer 34 increases. Therefore, the parasitic capacitance between the input/output pad 40 and the inductor 50 is further reduced with more layers in the gate stack 32.

As will be described later, the inductor 50 may be included in a receiving interface circuit. When configuring a receiving interface circuit using inductors, gain at high frequency may increase, and cut-off frequency may be enhanced.

As is well known, the performance of a receiving interface circuit is influenced not only by the inductance of the inductors but also the Q-factor of the inductors. The Q-factor of the inductors is related to capacitive coupling by the parasitic capacitance between the inductors and adjacent conductive patterns. As the parasitic capacitance increases, the Q-factor of the inductors decreases.

According to the embodiments of the present disclosure, by disposing the inductor 50 in the fifth lower wiring layer UM5, which is an uppermost layer among the lower wiring layers UM1, UM2, UM3, UM4 and UM5 of the peripheral structure 20, the magnitude of the parasitic capacitance between the inductor 50 and the substrate 10 and the magnitude of the parasitic capacitance between the inductor 50 and the input/output pad 40 may be relatively small. Therefore, the Q-factor of the inductor 50 may increase, and the SI characteristics of a receiving interface circuit configured using the inductor 50 may be improved.

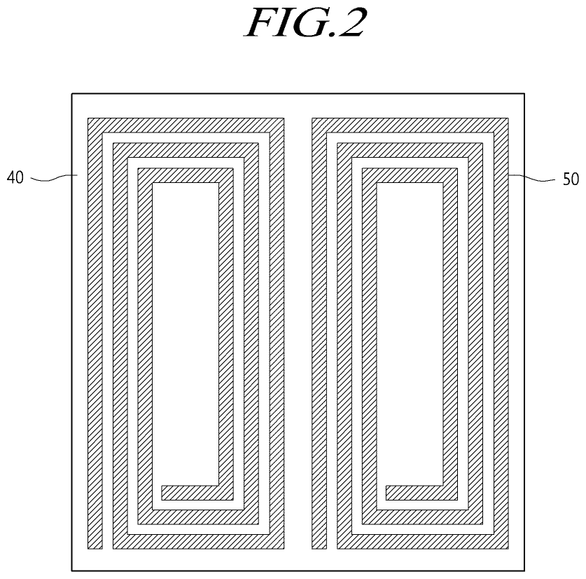

FIG. 2 is a plan view illustrating an input/output pad and inductors of FIG. 1.

Referring to FIG. 2, an inductor 50 vertically overlaps the input/output pad 40. In a plan view, the inductor 50 is disposed within the area of the input/output pad 40.

The inductor 50 may have a spiral shape. In FIG. 2, the inductor 50 has a quadrangular spiral shape, but other embodiments are not limited thereto. For example, the inductor 50 may have a circular or hexagonal spiral shape.

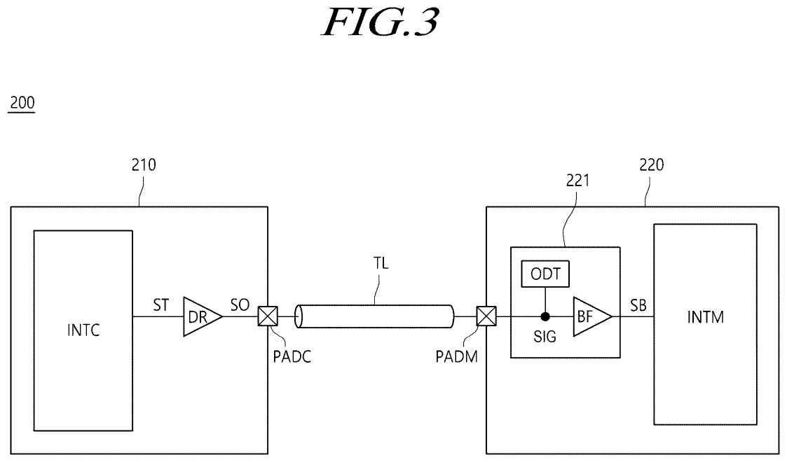

FIG. 3 is a block diagram illustrating a system including a semiconductor memory device according to embodiments of the present disclosure.

Referring to FIG. 3, a system 200 includes a first device 210, a second device 220, and a transmission line TL, which connects the first device 210 and the second device 220.

For example, the first device 210 may be a memory controller, and the second device 220 may be a semiconductor memory device according to the present disclosure. Although FIG. 3 illustrates, for the sake of convenience in explanation, a configuration for explaining one-way communication in which the first device 210 operates as a transmitting device and the second device 220 operates as a receiving device, each of the first device 210 and the second device 220 may perform a transmitting operation and a receiving operation, so that the system 200 may perform two-way communication.

In addition, although FIG. 3 illustrates, for the sake of convenience in explanation, only one a pair of input/output pads PADC and PADM and one transmission line TL to connect the pair of input/output pads PADC and PADM, each of the first device 210 and the second device 220 may include a plurality of input/output pads that are connected through a plurality of transmission lines.

A transmission driver DR of the first device 210 may output an output signal SO to the input/output pad PADC on the basis of a transmission signal ST from an internal circuit INTC. A receiving interface circuit 221 of the second device 220 may receive an input signal SIG through the input/output pad PADM and provide a buffer signal SB to an internal circuit INTM.

The receiving interface circuit 221 includes a termination circuit ODT, a buffer block BF, an amplifier circuit (not shown), and so on.

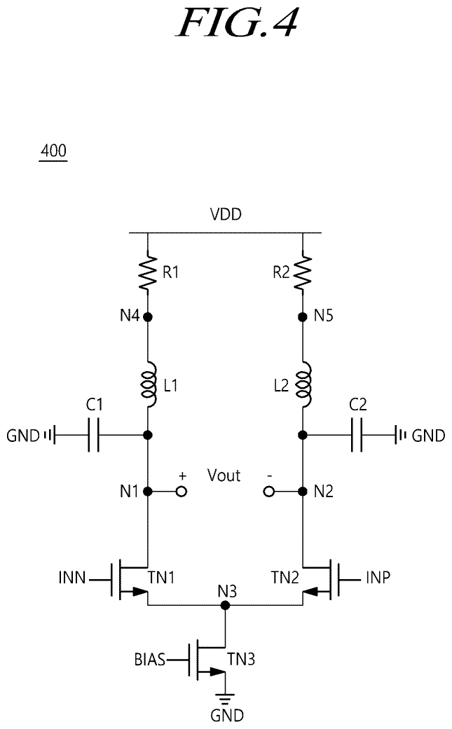

FIG. 4 is a circuit diagram illustrating an input buffer of a semiconductor memory device according to an embodiment of the present disclosure.

Referring to FIG. 4, a buffer block BF of FIG. 3 is illustrated as an input buffer 400 that includes a pair of differential input transistors TN1 and TN2, first and second resistors R1 and R2, and first and second inductors L1 and L2. In addition, the input buffer 400 further includes an enable transistor TN3 and first and second capacitors C1 and C2.

The pair of differential input transistors TN1 and TN2 include a first input transistor TN1, which is connected between a first node N1 and a third node N3, and a second input transistor TN2, which is connected between a second node N2 and the third node N3.

A first input signal INN is applied to the gate of the first input transistor TN1. A second input signal INP is applied to the gate of the second input transistor TN2. The first and second input signals INN and INP may be signals that are received through input/output pads from an external device.

The first input transistor TN1 changes the voltage level of the first node N1 on the basis of the first input signal INN. The first input transistor TN1 may be an N-channel MOS transistor. The drain of the first input transistor TN1 may be connected to the first node N1, the source of the first input transistor TN1 may be connected to the third node N3, and the gate of the first input transistor TN1 may receive the first input signal INN.

The second input transistor TN2 changes the voltage level of the second node N2 on the basis of the second input signal INP. The second input transistor TN2 may be an N-channel MOS transistor. The drain of the second input transistor TN2 may be connected to the second node N2, the source of the second input transistor TN2 may be connected to the third node N3, and the gate of the second input transistor TN2 may receive the second input signal INP.

The first resistor R1 and the first inductor L1 are connected in series between a power supply voltage terminal VDD and the first node N1. The first resistor R1 is connected between the power supply voltage terminal VDD and a fourth node N4, and the first inductor L1 is connected between the fourth node N4 and the first node N1.

The second resistor R2 and the second inductor L2 are connected in series between the power supply voltage terminal VDD and the second node N2. The second resistor R2 is connected between the power supply voltage terminal VDD and a fifth node N5, and the second inductor L2 is connected between the fifth node N5 and the second node N2.

Each of the first inductor L1 and the second inductor L2 may be an inductor 50 of FIG. 1.

The first capacitor C1 is connected between the first node N1 and a ground voltage terminal GND, and the second capacitor C2 is connected between the second node N2 and the ground voltage terminal GND.

The first input transistor TN1, the first inductor L1 and the first capacitor C1 are connected in common to the first node N1, the second input transistor TN2, the second inductor L2 and the second capacitor C2 are connected in common to the second node N2, and an output signal Vout is outputted through the first node N1 and the second node N2.

The enable transistor TN3 may connect the ground voltage terminal GND to the third node N3 on the basis of a bias voltage BIAS. When the enable transistor TN3 is turned on by the bias voltage BIAS, a current path may be formed between the first and second input transistors TN1 and TN2 and the ground voltage terminal GND. The enable transistor TN3 may be an N-channel MOS transistor. The drain of the enable transistor TN3 may be connected in common to the source of the first input transistor TN1 and the source of the second input transistor TN2, the source of the enable transistor TN3 may be connected to the ground voltage terminal GND, and the gate of the enable transistor TN3 may receive the bias voltage BIAS.

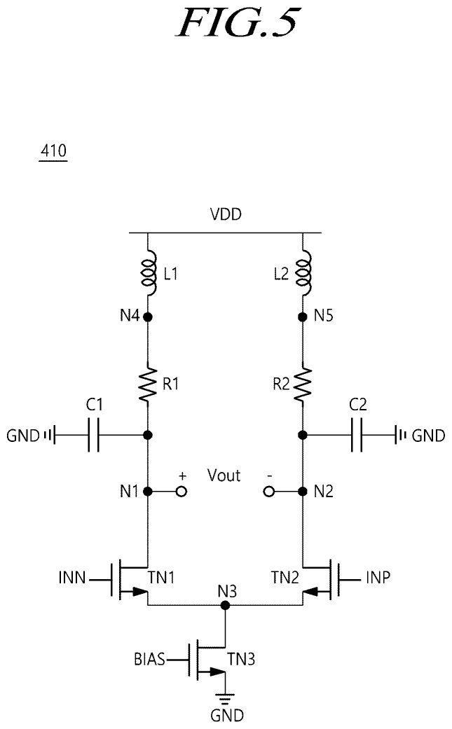

In FIG. 4, the first resistor R1 and the second resistor R2 are connected to the power supply voltage terminal VDD, the first inductor L1 is connected between the first resistor R1 and the first node N1, and the second inductor L2 is connected between the second resistor R2 and the second node N2. However, as will be described below with reference to FIG. 5, the locations of the first resistor R1 and the first inductor L1 may be exchanged, and the locations of the second resistor R2 and the second inductor L2 may be exchanged.

FIG. 5 is a circuit diagram illustrating an input buffer of a semiconductor memory device according to an embodiment of the present disclosure. For the sake of simplicity in explanation, elements or configurations that are the same or overlap with those described above with reference to FIG. 4 will be briefly described or omitted.

Referring to FIG. 5, a first inductor L1 and a first resistor R1 are connected in series between a power supply voltage terminal VDD and a first node N1. The first inductor L1 is connected between the power supply voltage terminal VDD and a fourth node N4, and the first resistor R1 is connected between the fourth node N4 and the first node N1.

A second inductor L2 and a second resistor R2 are connected in series between the power supply voltage terminal VDD and a second node N2. The second inductor L2 is connected between the power supply voltage terminal VDD and a fifth node N5, and the second resistor R2 is connected between the fifth node N5 and the second node N2.

Each of the first inductor L1 and the second inductor L2 may be an inductor 50 of FIG. 1.

A first input transistor TN1, the first resistor R1 and a first capacitor C1 are connected in common to the first node N1, a second input transistor TN2, the second resistor R2 and a second capacitor C2 are connected in common to the second node N2, and an output signal Vout of an input buffer 410 is outputted through the first node N1 and the second node N2.

In FIGS. 4 and 5, the first resistor R1 and the second resistor R2 are configured as load resistors, but the first resistor R1 may be replaced with the parasitic resistance component of a wiring that connects the first node N1 and the power voltage terminal VDD, and the second resistor R2 may be replaced with the parasitic resistance component of a wiring that connects the second node N2 and the power voltage terminal VDD. Therefore, the first resistor R1 and the second resistor R2 are omitted, and the ends of the first inductor L1 are connected to the power supply voltage terminal VDD and the first node N1, respectively, and the ends of the second inductor L2 are connected to the power supply voltage terminal VDD and the second node N2, respectively.

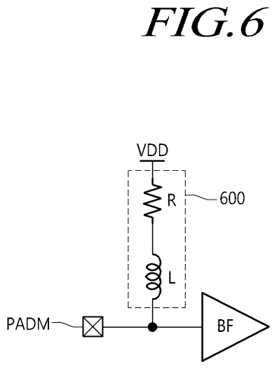

FIG. 6 is a circuit diagram illustrating a termination circuit of a semiconductor memory device according to an embodiment of the present disclosure.

Referring to FIG. 6, a termination circuit 600 includes a termination resistor R and an inductor L, which are connected between a power supply voltage terminal VDD and an input/output pad PADM.

The termination resistor R is connected between the power supply voltage terminal VDD and the inductor L. The inductor L is connected between the termination resistor R and the input/output pad PADM. The inductor L may be an inductor 50 of FIG. 1.

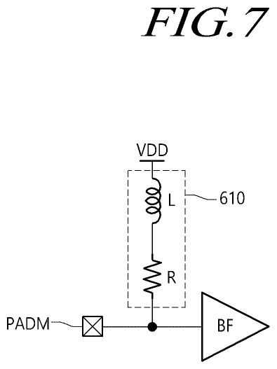

In FIG. 6, the termination resistor R is connected to the power supply voltage terminal VDD and the inductor L is connected between the termination resistor R and the input/output pad PADM, but as will be described below with reference to FIG. 7, the locations of the termination resistor R and the inductor L may be switched.

FIG. 7 is a circuit diagram illustrating a termination circuit of a semiconductor memory device according to an embodiment of the present disclosure.

Referring to FIG. 7, a termination circuit 610 includes an inductor L and a termination resistor R which are connected between a power supply voltage terminal VDD and an input/output pad PADM.

The inductor L is connected between the power supply voltage terminal VDD and the termination resistor R. The inductor L may be an inductor 50 of FIG. 1. The termination resistor R is connected between the inductor L and the input/output pad PADM.

In FIGS. 6 and 7, the termination resistor R is configured as a load resistor, but the termination resistor R may be replaced with the parasitic resistance component of a wiring that connects the power supply voltage terminal VDD and the input/output pad PADM. In this case, the termination resistor R is omitted, and the ends of the inductor L are connected to the power supply voltage terminal VDD and the input/output pad PADM, respectively.

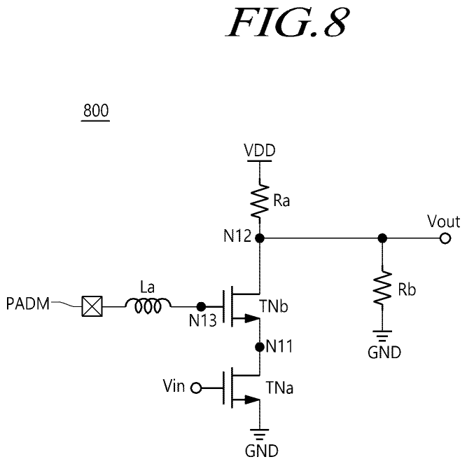

FIG. 8 is a diagram illustrating an amplifier circuit of a semiconductor memory device according to an embodiment of the present disclosure.

Referring to FIG. 8, an amplifier circuit 800 includes a first transistor TNa, a second transistor TNb, an inductor La, and first and second resistors Ra and Rb.

The first transistor TNa is connected between a ground voltage terminal GND and a first node N11. The first transistor TNa may receive an input signal Vin, may amplify the received input signal Vin, and may provide an amplified signal to the first node N11.

The first transistor TNa may be an N-channel MOS transistor. The drain of the first transistor TNa may be connected to the source of the second transistor TNb, the source of the first transistor TNa may be connected to the ground voltage terminal GND, and the gate of the first transistor TNa may receive the input signal Vin. The input signal Vin may be a signal that is provided from a semiconductor memory device including the amplifier circuit 800.

The second transistor TNb is connected between the first node N11 and a second node N12. The second transistor TNb may receive an amplified signal through the first node N11 from the first transistor TNa, and may provide an output signal Vout through the second node N12.

The second transistor TNb may be an N-channel MOS transistor. The source of the second transistor TNb is connected to the drain of the first transistor TNa, the drain of the second transistor TNb is connected to the second node N12, and the gate of the second transistor TNb is connected to a third node N13.

The inductor La is connected between the third node N13 and an input/output pad PADM. The inductor La may be an inductor 50 of FIG. 1. The first resistor Ra is connected between a power supply voltage terminal VDD and the second node N12. The second resistor Rb is connected between the second node N12 and the ground voltage terminal GND.

The second transistor TNb, the first resistor Ra and the second resistor Rb are commonly connected to the second node N12, and the output signal Vout of the amplifier circuit 800 is outputted through the second node N12.

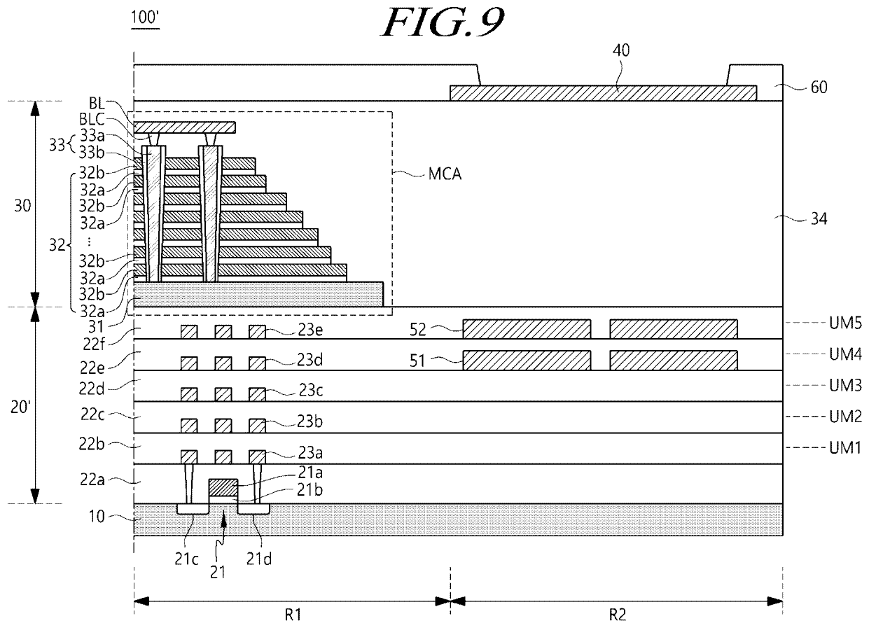

FIG. 9 is a cross-sectional view of a semiconductor memory device according to an embodiment of the present disclosure. For the sake of simplicity in explanation, elements or configurations that overlap with those described above with reference to FIG. 1 will be briefly described or omitted.

Referring to FIG. 9, a semiconductor memory device 100′ includes a substrate 10, a peripheral structure 20′, a memory structure 30, an input/output pad 40, a first inductor 51, and a second inductor 52.

The first inductor 51 and the second inductor 52 vertically overlap the input/output pad 40.

The second inductor 52 is disposed in a fifth lower wiring layer UM5, which is an uppermost layer among lower wiring layers UM1, UM2, UM3, UM4 and UM5 included in the peripheral structure 20′. The first inductor 51 is disposed in a fourth lower wiring layer UM4, which is a second uppermost layer among the lower wiring layers UM1, UM2, UM3, UM4 and UM5 included in the peripheral structure 20′.

The fifth lower wiring layer UM5 is disposed closest to the memory structure 30 among the lower wiring layers UM1, UM2, UM3, UM4 and UM5 included in the peripheral structure 20′, and the fourth lower wiring layer UM4 is disposed closest to the fifth lower wiring layer UM5 among the lower wiring layers UM1, UM2, UM3 and UM4 included in

### The Peripheral Structure 20′.

The second inductor 52 is disposed farther away from the substrate 10 than the first inductor 51. The parasitic capacitance between the second inductor 52 and the substrate 10 has a smaller value than the parasitic capacitance between the first inductor 51 and the substrate 10.

Although not illustrated, each of the first and second inductors 51 and 52 may have a spiral shape in a plan view. The spiral rotation direction of the first inductor 51 and the spiral rotation direction of the second inductor 52 may be opposite to each other. For example, the rotation direction of the first inductor 51 may be counterclockwise, and the rotation direction of the second inductor 52 may be clockwise.

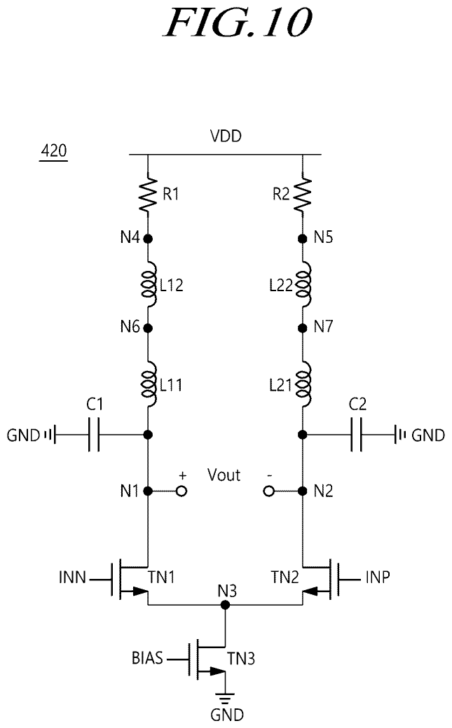

FIG. 10 is a circuit diagram illustrating an input buffer of a semiconductor memory device according to an embodiment of the present disclosure. For the sake of simplicity in explanation, elements or configurations that overlap with those described above with reference to FIG. 4 will be briefly described or omitted.

Referring to FIG. 10, an input buffer 420 includes a pair of differential input transistors TN1 and TN2, first and second resistors R1 and R2, and first, second, third and fourth inductors L11, L12, L21 and L22. In addition, the input buffer 420 further includes an enable transistor TN3 and first and second capacitors C1 and C2.

The first inductor L11, the second inductor L12 and the first resistor R1 are connected in series between a first node N1 and a power supply voltage terminal VDD. The first inductor L11 is connected between the first node N1 and a sixth node N6, the second inductor L12 is connected between the sixth node N6 and a fourth node N4, and the first resistor R1 is connected between the fourth node N4 and the power supply voltage terminal VDD.

The third inductor L21, the fourth inductor L22 and the second resistor R2 are connected in series between a second node N2 and the power supply voltage terminal VDD. The third inductor L21 is connected between the second node N2 and a seventh node N7, the fourth inductor L22 is connected between the seventh node N7 and a fifth node N5, and the second resistor R2 is connected between the fifth node N5 and the power voltage terminal VDD.

A first input transistor TN1, the first inductor L11 and the first capacitor C1 are connected in common to the first node N1. A second input transistor TN2, the third inductor L21 and the second capacitor C2 are connected in common to the second node N2. An output signal Vout is outputted through the first node N1 and the second node N2.

Each of the first inductor L11 and the third inductor L21 may be a first inductor 51 of FIG. 9. Each of the second inductor L12 and the fourth inductor L22 may be a second inductor 52 of FIG. 9. The parasitic capacitance between the first and third inductors L11 and L21 and the substrate 10 may have a larger value than the parasitic capacitance between the second and fourth inductors L12 and L22 and the substrate 10.

When the first and third inductors L11 and L21, which are connected to the output nodes N1 and N2, are configured with the first inductors 51 of FIG. 9 that have a relatively larger parasitic capacitance, and the second and fourth inductors L12 and L22 are configured with the second inductors 52 of FIG. 9 that have relatively smaller parasitic capacitance, compared to an opposite case in which the first and third inductors L11 and L21 are configured with the second inductors 52 of FIG. 9 and the second and fourth inductors L12 and L22 are configured with the first inductors 51 of FIG. 9, a magnitude by which cut-off frequency decreases due to parasitic capacitance may be reduced.

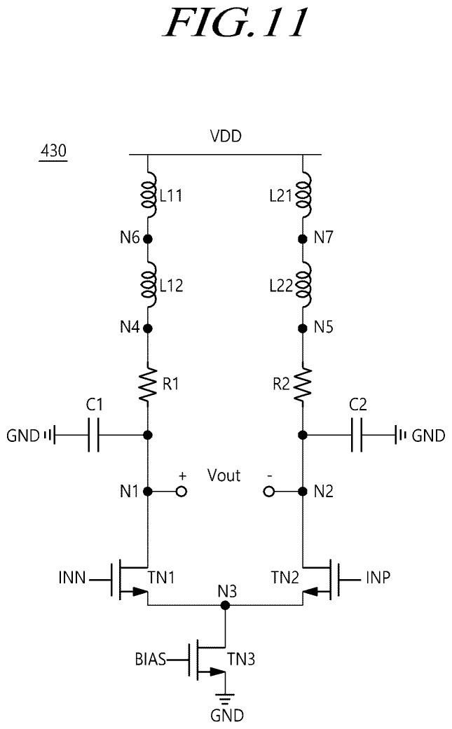

FIG. 11 is a circuit diagram illustrating an input buffer of a semiconductor memory device according to an embodiment of the present disclosure. For the sake of simplicity in explanation, elements or configurations that overlap those described above with reference to FIG. 10 will be briefly described or omitted.

Referring to an input buffer 430 of FIG. 11, a first resistor R1, a second inductor L12 and a first inductor L11 are connected in series between a first node N1 and a power supply voltage terminal VDD. The first resistor R1 is connected between the first node N1 and a fourth node N4, the second inductor L12 is connected between the fourth node N4 and a sixth node N6, and the first inductor L11 is connected between the sixth node N6 and the power supply voltage terminal VDD.

A second resistor R2, a fourth inductor L22 and a third inductor L21 are connected in series between a second node N2 and the power supply voltage terminal VDD. The second resistor R2 is connected between the second node N2 and a fifth node N5, the fourth inductor L22 is connected between the fifth node N5 and a seventh node N7, and the third inductor L21 is connected between the seventh node N7 and the power voltage terminal VDD.

A first input transistor TN1, the first resistor R1 and a first capacitor C1 are connected in common to the first node N1. A second input transistor TN2, the second resistor R2 and a second capacitor C2 are connected in common to the second node N2. An output signal Vout is outputted through the first node N1 and the second node N2.

Each of the first inductor L11 and the third inductor L21 may be a first inductor 51 of FIG. 9. Each of the second inductor L12 and the fourth inductor L22 may be a second inductor 52 of FIG. 9. The parasitic capacitance between the first and third inductors L11 and L21 and the substrate 10 may have a larger value than the parasitic capacitance between the second and fourth inductors L12 and L22 and the substrate 10.

When the first and third inductors L11 and L21, which are connected to the power supply voltage terminal VDD, are configured with the first inductors 51 of FIG. 9 that have relatively larger parasitic capacitance and the second and fourth inductors L12 and L22 are configured with the second inductors 52 of FIG. 9 that have relatively smaller parasitic capacitance, compared to an opposite case in which the first and third inductors L11 and L21 are configured with the second inductors 52 of FIG. 9 and the second and fourth inductors L12 and L22 are configured with the first inductors 51 of FIG. 9, a magnitude by which cut-off frequency decreases due to parasitic capacitance may be reduced.

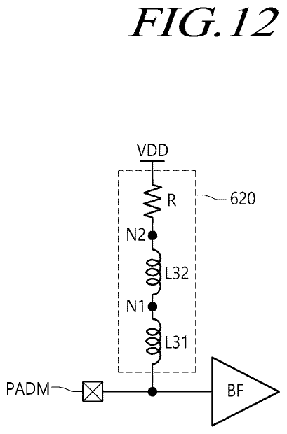

FIG. 12 is a circuit diagram illustrating a termination circuit of a semiconductor memory device according to an embodiment of the present disclosure.

Referring to FIG. 12, a termination circuit 620 includes a first inductor L31, a second inductor L32 and a termination resistor R, which are connected in series between an input/output pad PADM and a power supply voltage terminal VDD.

The first inductor L31 is connected between the input/output pad PADM and a first node N1. The second inductor L32 is connected between the first node N1 and a second node N2. The termination resistor R is connected between the second node N2 and the power supply voltage terminal VDD.

The first inductor L31 may be a first inductor 51 of FIG. 9, and the second inductor L32 may be a second inductor 52 of FIG. 9. The parasitic capacitance between the first inductor L31 and the substrate 10 may have a larger value than the parasitic capacitance between the second inductor L32 and the substrate 10.

When the first inductor L31, which is connected to the input/output pad PADM, is configured with the first inductor 51 of FIG. 9 that has a relatively larger parasitic capacitance and the second inductor L32 is configured with the second inductor 52 of FIG. 9 that has a relatively smaller parasitic capacitance, compared to an opposite case in which the first inductor L31 is configured with the second inductor 52 of FIG. 9 and the second inductor L32 is configured with the first inductor 51 of FIG. 9, a magnitude by which a cut-off frequency decreases due to parasitic capacitance may be reduced.

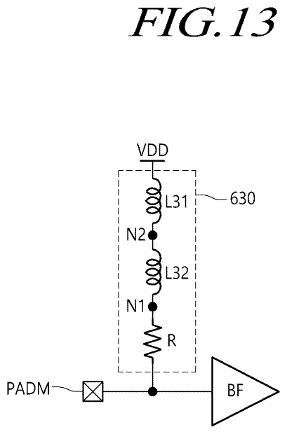

Referring to FIG. 13, a termination circuit 630 includes a termination resistor R, a second inductor L32 and a first inductor L31, which are connected in series between an input/output pad PADM and a power supply voltage terminal VDD.

The termination resistor R is connected between the input/output pad PADM and a first node N1. The second inductor L32 is connected between the first node N1 and a second node N2. The first inductor L31 is connected between the second node N2 and the power supply voltage terminal VDD.

The first inductor L31 may be a first inductor 51 of FIG. 9, and the second inductor L32 may be a second inductor 52 of FIG. 9. The parasitic capacitance between the first inductor L31 and the substrate 10 may have a larger value than the parasitic capacitance between the second inductor L32 and the substrate 10.

When the first inductor L31, which is connected to the power supply voltage terminal VDD, is configured with the first inductor 51 of FIG. 9 having a relatively larger parasitic capacitance and the second inductor L32 is configured with the second inductor 52 of FIG. 9 having a relatively smaller parasitic capacitance, compared to an opposite case in which the first inductor L31 is configured with the second inductor 52 of FIG. 9 and the second inductor L32 is configured with the first inductor 51 of FIG. 9, a magnitude by which a cut-off frequency decreases due to parasitic capacitance may be reduced.

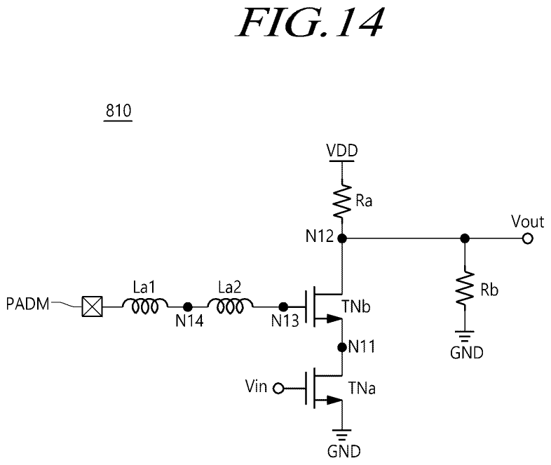

FIG. 14 is a circuit diagram illustrating an amplifier circuit of a semiconductor memory device according to an embodiment of the present disclosure. For the sake of simplicity in explanation, elements or configurations that overlap those described above with reference to FIG. 8 will be briefly described or omitted.

Referring to FIG. 14, an amplifier circuit 810 includes a first transistor TNa, a second transistor TNb, first and second inductors La1 and La2, and first and second resistors Ra and Rb.

The first inductor La1 and the second inductor La2 are connected in series between an input/output pad PADM and a third node N13. The first inductor La1 is connected between the input/output pad PADM and a fourth node N14, and the second inductor La2 is connected between the fourth node N14 and the third node N13.

The first inductor La1 may be a first inductor 51 of FIG. 9, and the second inductor La2 may be a second inductor 52 of FIG. 9. The parasitic capacitance between the first inductor La1 and the substrate 10 may have a larger value than the parasitic capacitance between the second inductor La2 and the substrate 10.

When the first inductor La1, which is connected to the input/output pad PADM, is configured with the first inductor 51 of FIG. 9 having a relatively larger parasitic capacitance and the second inductor La2 is configured with the second inductor 52 of FIG. 9 having a relatively smaller parasitic capacitance, compared to an opposite case in which the first inductor La1 is configured with the second inductor 52 of FIG. 9 and the second inductor La2 is configured with the first inductor 51 of FIG. 9, a magnitude by which a cut-off frequency decreases due to parasitic capacitance may be reduced.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor memory device comprising:
a substrate;
a peripheral structure including a plurality of lower wiring layers that are vertically stacked on the substrate;
a memory structure disposed on the peripheral structure, and including a memory cell array in a first region;
an input/output pad disposed over the memory structure in a second region; and
an inductor disposed in at least one of the plurality of lower wiring layers and to vertically overlap the input/output pad.

2. The semiconductor memory device according to claim 1,
wherein the plurality of lower wiring layers comprises:
a first lower wiring layer disposed on the substrate; and
a second lower wiring layer disposed over the first lower wiring layer, and
wherein the inductor is disposed in the second lower wiring layer.

3. The semiconductor memory device according to claim 2, wherein the second lower wiring layer, from among the plurality of lower wiring layers, is disposed closest to the memory structure.

4. The semiconductor memory device according to claim 1, wherein a conductive pattern is not disposed between the inductor and the substrate.

5. The semiconductor memory device according to claim 1, wherein a conductive pattern is not disposed between the inductor and the input/output pad.

6. The semiconductor memory device according to claim 1, wherein the memory cell array comprises:
a plurality of electrode layers and a plurality of interlayer insulating layers alternately stacked; and
a cell plug penetrating the plurality of electrode layers and the plurality of interlayer insulating layers.

7. The semiconductor memory device according to claim 1, wherein
the peripheral structure further includes a receiving interface circuit that includes the inductor and is connected to the input/output pad.

8. The semiconductor memory device according to claim 1
wherein the peripheral structure further includes a receiving interface circuit that comprises an input buffer,
wherein the input buffer comprises:
a first input transistor configured to change a voltage level of a first output node in response to a first input signal;
a second input transistor configured to change a voltage level of a second output node in response to a second input signal;
a resistor connected to a power supply voltage terminal; and
the inductor, and
wherein the inductor is connected between any one of the first and second output nodes and the resistor.

9. The semiconductor memory device according to claim 1,
wherein the peripheral structure further includes a receiving interface circuit that comprises an input buffer,
wherein the input buffer comprises:
a first input transistor configured to change a voltage level of a first output node in response toa first input signal;
a second input transistor configured to change a voltage level of a second output node in response to a second input signal;
a resistor connected to any one of the first and second output nodes; and
the inductor, and
wherein the inductor is connected between a power supply voltage terminal and the resistor.

10. The semiconductor memory device according to claim1,
wherein the peripheral structure further includes a receiving interface circuit that comprises an input buffer,
wherein the input buffer comprises:
a first input transistor configured to change a voltage level of a first output node in response to a first input signal;
a second input transistor configured to change a voltage level of a second output node in response to a second input signal; and
the inductor, and
wherein one end of the inductor is connected to a power supply voltage terminal and the other end of the inductor is connected to any one of the first and second output nodes.

11. The semiconductor memory device according to claim 1,
wherein the peripheral structure further includes a receiving interface circuit that comprises a termination circuit,
wherein the termination circuit comprises:
a resistor connected to a power supply voltage terminal; and
the inductor, and
wherein the inductor is connected between the input/output pad and the resistor.

12. The semiconductor memory device according to claim 1,
wherein the peripheral structure further includes a receiving interface circuit that comprises a termination circuit,
wherein the termination circuit comprises:
a resistor connected to the input/output pad; and
the inductor, and
wherein the inductor is connected between a power supply voltage terminal and the resistor.

13. The semiconductor memory device according to claim 1,
wherein the peripheral structure further includes a receiving interface circuit that comprises a termination circuit,
wherein the termination circuit comprises:
the inductor, and
wherein one end of the inductor is connected to a power supply voltage terminal and the other end of the inductor is connected to the input/output pad.

14. The semiconductor memory device according to claim 1,
wherein the peripheral structure further includes a receiving interface circuit that comprises an amplifier circuit,
wherein the amplifier circuit comprises:
a first transistor connected between a ground voltage terminal and a first node, and configured to change a voltage level of the first node on the basis of an input signal;
a second transistor connected between the first node and an output node, and configured to provide an output signal to the output node; and
the inductor, and
wherein the inductor is connected between the input/output pad and a gate of the second transistor.

15. A semiconductor memory device comprising:
a substrate;
a peripheral structure including a first lower wiring layer over the substrate and a second lower wiring layer over the first lower wiring layer;
a memory structure disposed on the peripheral structure, and including a three-dimensional memory cell array in a first region;
an input/output pad disposed over the memory structure in a second region;
a first inductor disposed in the first lower wiring layer to vertically overlap the input/output pad; and
a second inductor disposed in the second lower wiring layer to vertically overlap the input/output pad.

16. The semiconductor memory device according to claim 15, wherein a conductive pattern is not disposed between the first inductor and the substrate.

17. The semiconductor memory device according to claim 15, wherein a conductive pattern is not disposed between the second inductor and the input/output pad.

18. The semiconductor memory device according to claim 15, wherein
the peripheral structure further includes a receiving interface circuit that is connected to the input/output pad, and
the receiving interface circuit includes the first and second inductors.

19. The semiconductor memory device according to claim 15,
the peripheral structure further includes a receiving interface circuit that is connected to the input/output pad and that comprises an input buffer,
wherein the input buffer comprises:
a first input transistor configured to change a voltage level of a first output node on the basis of a first input signal;
a second input transistor configured to change a voltage level of a second output node on the basis of a second input signal;
a resistor connected to a power supply voltage terminal; and
the first and second inductors,
wherein the first inductor is connected to any one of the first and second output nodes, and
wherein the second inductor is connected between the first inductor and the resistor.

20. The semiconductor memory device according to claim 15,
the peripheral structure further includes a receiving interface circuit that is connected to the input/output pad and that comprises an input buffer,
wherein the input buffer comprises:
a first input transistor configured to change a voltage level of a first output node on the basis of a first input signal;
a second input transistor configured to change a voltage level of a second output node on the basis of a second input signal;
a resistor connected to any one of the first and second output nodes; and
the first and second inductors,
wherein the first inductor is connected to a power supply voltage terminal, and
wherein the second inductor is connected between the resistor and the first inductor.

21. The semiconductor memory device according to claim 15,
the peripheral structure further includes a receiving interface circuit that is connected to the input/output pad and that comprises a termination circuit,
wherein the termination circuit comprises:
a resistor connected to a power supply voltage terminal; and
the first and second inductors,
wherein the first inductor is connected to the input/output pad, and
wherein the second inductor is connected between the resistor and the first inductor.

22. The semiconductor memory device according to claim 15,
the peripheral structure further includes a receiving interface circuit that is connected to the input/output pad and that comprises a termination circuit,
wherein the termination circuit comprises:
a resistor connected to the input/output pad; and
the first and second inductors,
wherein the first inductor is connected to a power supply voltage terminal, and
wherein the second inductor is connected between the resistor and the first inductor.

23. The semiconductor memory device according to claim 15,
the peripheral structure further includes a receiving interface circuit that is connected to the input/output pad and that comprises an amplifier circuit,
wherein the amplifier circuit comprises:
a first transistor connected between a ground voltage terminal and a first node, and configured to change a voltage level of the first node on the basis of an input signal;
a second transistor connected between the first node and an output node, and configured to provide an output signal to the output node; and
the first and second inductors,
wherein the first inductor is connected to the input/output pad, and
wherein the second inductor is connected between the first inductor and a gate of the second transistor.
